(19) United States
(12) Patent Application Publication
(10) Pub. No.: US 2010/0258950 A1
(43) Pub. Date: Oct. 14, 2010

(54) PACKAGE WITH SEMICONDUCTOR DEVICE AND INTEGRATED CIRCUIT MOUNTED THEREIN AND METHOD FOR MANUFACTURING SUCH PACKAGE

(76) Inventors: GANG LI, SuZhou (CN); Wei Hu, SuZhou (CN); Jia-Xin Mei, SuZhou (CN)

Correspondence Address: Flash Intellectual Property, Inc.;Attn. Cheng-Ju Chiang, P.O. Box 766, Chino, CA, 91708, US

(21) Appl. No.: 12/544,415

(22) Filed: Aug. 20, 2009

(30) Foreign Application Priority Data
Apr. 14, 2009 (CN) 200910049305.0

(51) Int. Cl. H01L 23/52; H01L 21/50

(52) U.S. Cl. 257/777; 438/107; 257/E23.141; 257/E21.499

(57) ABSTRACT

A multichip package includes a first chip and a second chip coupled with the first chip. The first chip includes a first base with a semiconductor device mounted on one side of the first base, a first electrical connection unit, a first bonding ring surrounding the semiconductor device, a first insulating layer formed on the other side of the first base and a first external bonding portion formed on the first insulating layer. The first external bonding portion is electrically connected to the first electrical connection unit. The second chip includes an integrated circuit corresponding to the semiconductor device, a second electrical connection unit fusing with the first electrical connection unit, and a second bonding ring fusing with the first bonding ring in order to form a hermetic cavity surrounding the semiconductor device, the integrated circuit, the first electrical connection unit and the second electrical connection unit.

### BACKGROUND OF THE INVENTION

1. Field of the Invention

The present invention relates to a package with a semiconductor device and an integrated circuit both mounted therein and a method for manufacturing such package, and more particularly to a multichip wafer-level package and a method for making the same.

2. Description of Related Art

MEMS technology is an advanced technology with fast development speed in recent years and is promoting a change in semiconductor industry. The MEMS products begin to be widely used in many aspects including car, industry control, aerospace and medical etc. With the MEMS technology becoming more and more practical, the MEMS products are estimated to be broadly used in printer, projector, handset, DSC, game, computer etc. before long. Comparing with the traditional electronic components, the MEMS products have advantages in profile, power dissipation, weight and price etc. Besides, the MEMS products can be of mass production through advanced semiconductor process. Nowadays, the existing MEMS products are actually applied in pressure sensors, accelerometers and silicon microphones etc.

However, the MEMS components also need other function modules including driver, switching, signal processing etc. electrically connected with each other to jointly form an independent system for integrated function. There are mainly two kinds of integration solutions called single-chip integration and multi-chip integration, respectively. Regarding to the single-chip integration, there are two kinds of processes among which one is called pre-CMOS and the other is called POST-CMOS determined by the manufacture sequence of the mountable components. Pre-CMOS is a kind of process with the MEMS component fabricated before the electronic circuitry in a same chip. However, this process may result in polluting the later electronic circuitry and may further pollute the corresponding manufacture machine. As a result, any other integrated circuits manufactured by such manufacture machine with the process may also be disabled. In a POST-CMOS process, the MEMS component is fabricated after the electronic circuitry. Usually, the MEMS component needs high temperature in manufacturing, which may easily damage the integrated circuitry. Although, disadvantages arising from the Pre-CMOS process and the POST-CMOS process can be avoided by certain methods. However, such avoidance will result in the complexity of the process and accordingly enhance the manufacture cost. Due to the above-described reasons, many MEMS components are selected to avoid using the single-chip integration process.

The multi-chip integration is another process with the MEMS component and the integrated circuitry enclosed in a single encapsulation. In this process, different chips are firstly selected for mounting the MEMS component and the integrated circuitry respectively, and then the chips are adjacently arranged in a same chip base. Line circuits are provided for electrically connecting the MEMS component and the integrated circuitry. Finally, the first and the second chips can be packed through expensive ceramic or metal process. However, since the connected length of the integrated circuitry is relative long, which may enters multiple Interrupted signals as a result that the integration function of the system may be greatly influenced.

Another advanced packing method includes providing a first chip mounted with a MEMS component and a second chip mounted with an integrated circuitry, and then the first and the second chips are coupled together, and finally to be packed. FIG. 1 shows a first wafer 1 and a second wafer 2 before coupling with each other. The second wafer 2 includes a plurality of second chips 502 each with a MEMS device 501 mounted thereon. The first wafer 1 includes a plurality of first chips 504 each including an integrated circuit 503. A bonding ring 505 is provided for sealing the MEMS device 501 and the integrated circuit 503. An electrical connection portion 506 of each second chip 502 fuses with a corresponding electrical connection portion 507 of the first chip 501 to establish an electrical connection between the MEMS device and the integrated circuit. Besides, an external bonding portion 508 located outside of the bonding ring 505 is formed on the electrical connection portion 507 for electrically connecting to an external circuit. After the first and the second wafers 1, 2 fused with each other to form a combination, cutting processes are provided dividing the combination in order to get multiple independent integrated components. Each integrated component can be plastically packed in order to save cost, and can lower the profile of the forming package and reduce the spurious capacitances as well. However, since the first chip 504 is provided with an elongated part for mounting the external bonding portion 508 as a result that the area of the first chip 504 is much larger than that of the second chip 502, and easy to understand that more material of the first chip 504 is wasted. Besides, in this arrangement, the first and the second wafers 1, 2 can't be cut simultaneously in cutting process. Instead, the second wafer 2 and the first wafer 1 are cut one by one, which will complicate the cutting process and make the cutting process difficult for being controlled.

Hence, it is desired to have a package with improved structure and an improved method for manufacturing the package in order to solve the problems above.

### BRIEF SUMMARY OF THE INVENTION

A multichip package includes a first chip and a second chip coupled with the first chip. The first chip includes a first base with a semiconductor device mounted on one side of the first base, a first electrical connection unit, a first bonding ring surrounding the semiconductor device, a first insulating layer formed on the other side of the first base and a first external bonding portion formed on the first insulating layer. The first external bonding portion is electrically connected to the first electrical connection unit and is adapted for being mounted on an external circuit. The second chip includes an integrated circuit corresponding to the semiconductor device, a second electrical connection unit fusing with the first electrical connection unit, and a second bonding ring fusing with the first bonding ring in order to form a hermetic cavity surrounding the semiconductor device, the integrated circuit, the first electrical connection unit and the second electrical connection unit. The first external bonding portion is disposed on the other side of the first base as a result that the package can be formed by simultaneously cutting first and second wafers with the first and the second chips mounted thereon in order to save material of the first and the second chips. The package can be plastically packed or can be directly adapted for SMT or Flip-Chip Solder process for lower cost.

The foregoing has outlined rather broadly the features and technical advantages of the present invention in order that the detailed description of the invention that follows may be better understood. Additional features and advantages of the invention will be described hereinafter which form the subject of the claims of the invention.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a perspective view of a pair of first and second existing wafers mounted with electronic components in the prior art for being coupled with each other;

FIG. 2 is a schematic cross-sectional view of an integrated component cut out from the coupled wafers to show structures of a MEMS device and an integral circuit of the first and the second wafers, respectively;

FIG. 3 is a schematic cross-sectional view of a package with a MEMS device and an integral circuit disposed therein according to a first embodiment of the present invention;

FIG. 4 is a schematic cross-sectional view of a first chip of the package according to the first embodiment of the present invention;

FIG. 5 is a schematic top view of the first chip shown in FIG. 4;

FIG. 6 is a cross-sectional view of a second chip of the package according to the first embodiment of the present invention;

FIG. 7 is a schematic top view of the second chip shown in FIG. 6;

FIG. 8 is a top view of a second wafer provided for making the package;

FIG. 9 is a top view of a first wafer provided for making the package together with the second wafer;

FIG. 10 is a perspective view of the first and the second wafers before coupling with each other;

FIG. 11 is a perspective view of the first and the second independent chips cut out from the coupled first and the second wafers;

FIG. 12 is a cross-sectional view of the first and the second chips before mating with each other;

FIG. 13 is a cross-sectional view of the first and the second chips coupled with each other;

FIG. 14 is a schematic cross-sectional view for making the package showing a step of defining a through hole in a first base of the first chip when the first and the second chips are coupled with each other;

FIG. 15 is a schematic cross-sectional view for making the package showing a step of depositing a first insulating layer on a back wall of the first base;

FIG. 16 is a schematic cross-sectional view for making the package showing a step of forming a first external bonding portion disposed on the first insulating layer;

FIG. 17 is a schematic cross-sectional view of an independent package according to the first embodiment of the present invention cut out from the coupled first and the second wafers; and

FIG. 18 is schematic cross-sectional view of another package according to a second embodiment of the present invention.

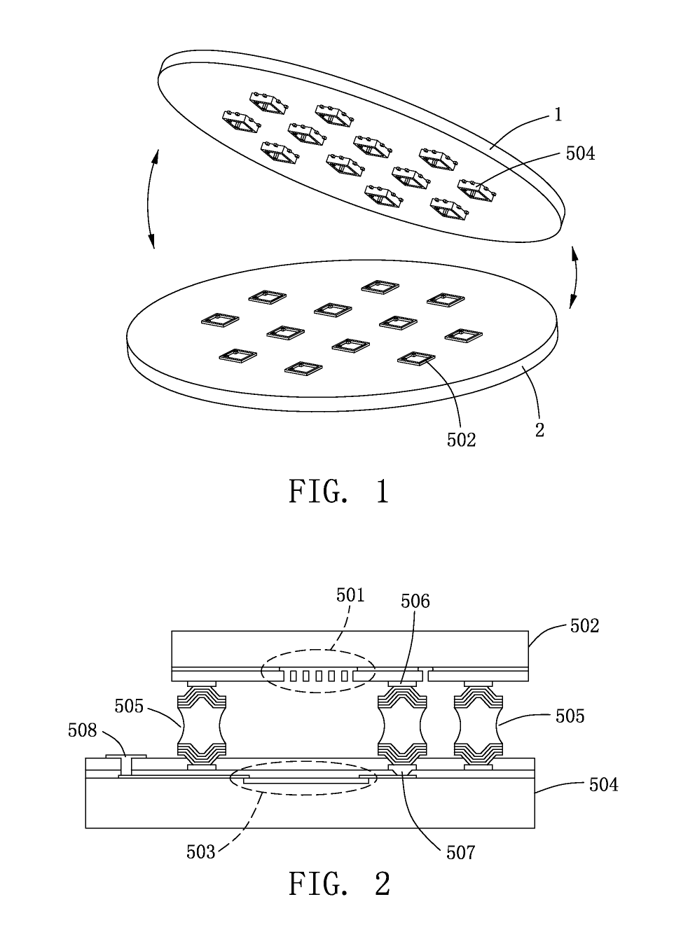

### DETAILED DESCRIPTION OF THE PREFERRED EMBODIMENT

In the following description, numerous specific details are set forth to provide a thorough understanding of the present invention. However, it will be obvious to those skilled in the art that the present invention may be practiced without such specific details. In other instances, well-known circuits have been shown in block diagram form in order not to obscure the present invention in unnecessary detail. For the most part, details concerning timing considerations and the like have been omitted inasmuch as such details are not necessary to obtain a complete understanding of the present invention and are within the skills of persons of ordinary skill in the relevant art.

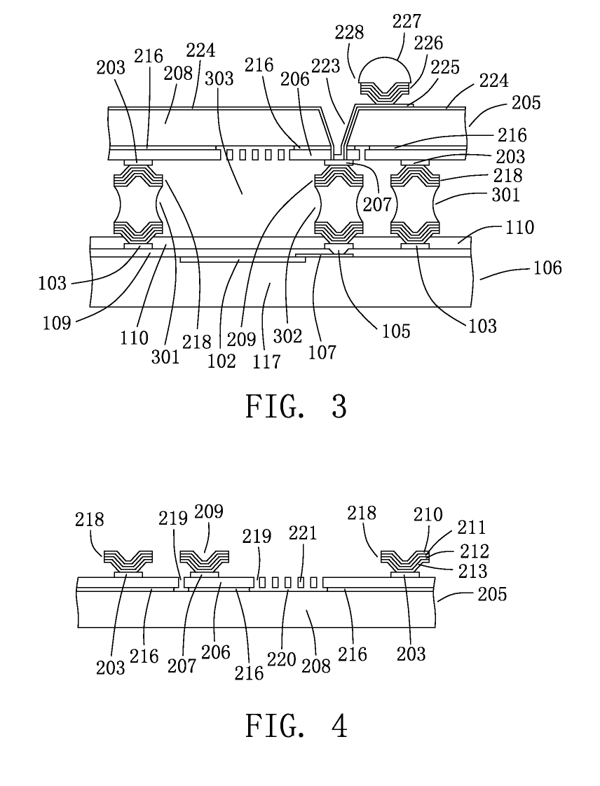

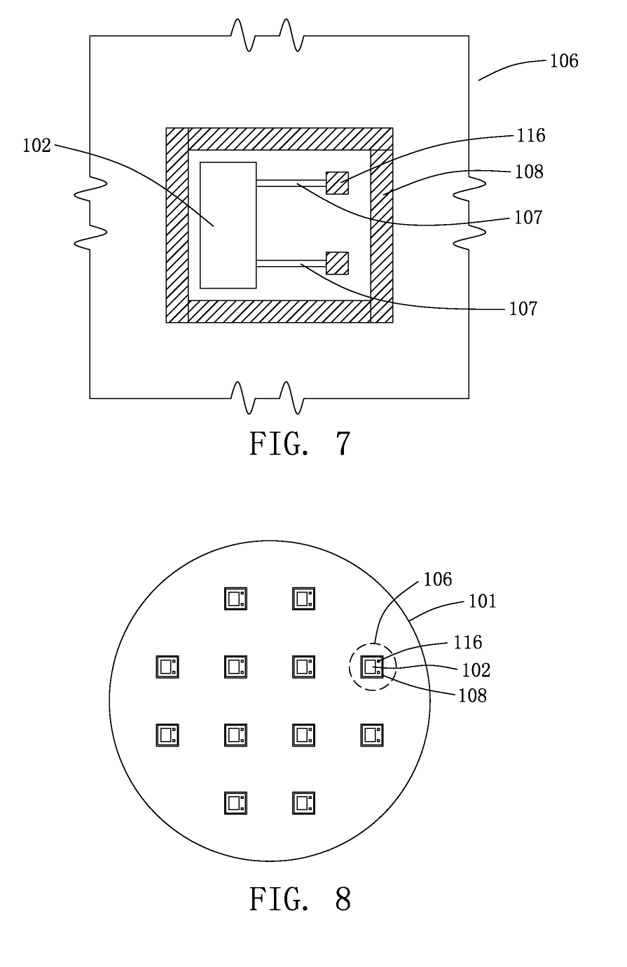

Please refer to FIGS. 3-7, a multichip wafer-level package according to a first embodiment of the present invention is disclosed. The package includes at least one first chip 205 and at least one second chip 106 for being coupled with each other. The first chip 205 includes a first base 208, a silica layer 216 formed on one side of the first base 208, a MEMS layer 206 formed on the silica layer 216, a first bonding pad 207, a first bonding ring 218, a first insulating layer 224 formed on the other side of the first base 208, and a first external bonding portion 228 formed on the first insulating layer 224. The first external bonding portion 228 is electrically connected to the first bonding pad 207. The first insulating layer can be formed of a silica or a silicon nitride or the like.

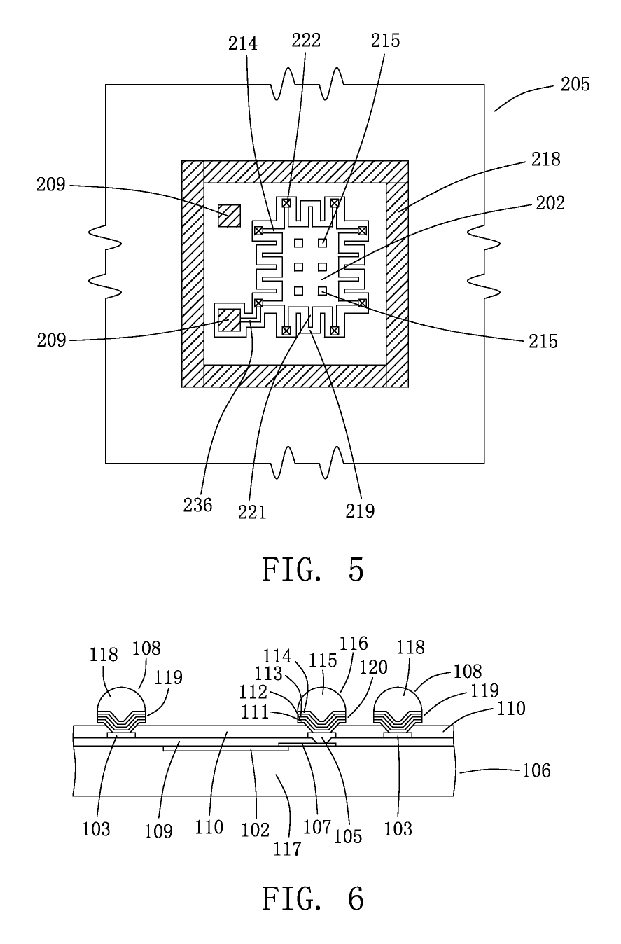

Please refer to FIGS. 4 and 5, a plurality of slits 219 are etched on the MEMS layer 206 in order to form a MEMS device such as a comb capacitive accelerometer 202. The accelerometer 202 includes plurality of release holes 215 defined in its mass block, a fixing girder 214 adapted for hanging the mass block, a first electrical connection unit, and a plurality of circuit lines 236 for electrically connecting the combs 221 of the accelerometer 202 and the corresponding first bonding pad 207. The fixing girder 214 includes a pivot 222 located at a lateral side thereof for supporting the mass block.

The first electrical connection unit includes the first bonding pad 207 and a pair of first additional bonding pads 209 formed on the first bonding pad 207. The first bonding pad 207 is made of metal material. The first bonding pad 207 and the pair of first additional bonding pads 209 are surrounded by the first bonding ring 218. Each first additional bonding pad 209 is formed by a first under bump metallurgy (UBM) which will be detailed hereinafter.

The first bonding ring 218 includes a first metal ring 203 and a UBM disposed on the first metal ring 203 wherein the UBM comprises an adhesion layer 213, a diffusion barrier layer 212, a wetting layer 211 and an oxidation barrier layer 210. The adhesion layer 213 is adapted for affixing the first bonding ring 218 and the metal ring 203 to prevent the first bonding ring 218 from being broken away from the metal ring 203. The adhesion layer 213 can be formed of at least one material of Cr, Ti, TiW etc. The diffusion barrier layer 212 is employed for prohibiting the material of wetting layer 211 penetrating the first chip 205. The diffusion barrier layer 212 can be formed of at least one material of Pb, Pt, Cu etc. The wetting layer 211 can prohibit oxidation of the adhesion layer 213 and the diffusion barrier layer 212. The wetting layer 211 is usually formed of at least one selective material of Cu, Au, Ni etc. The oxidation barrier layer 210 can be formed of Au. The structure and function of the first UBM is the same as the UBM described above, so detailed structure of the first UBM is omitted herein.

The first external bonding portion 228 is a solder ball 227 which includes an electrical connecting layer 225, an additional UBM layer 226 formed on the connecting layer 225, a solder layer formed on the UBM layer 226. The additional UBM layer 226 is the same as the first UBM layer 206. The solder layer can be formed of a first alloy of Sn, Ag, Cu, or a second alloy of Sn, Cu, Ni, or a third alloy of Sn, Au, or other alloys.

The second chip 106 is adapted for mating with the first chip 205 and comprises a second base 117, an integrated circuit 102 opposite to the accelerometer 202, a second electrical connection unit for fusing with the first electrical connection unit, and a second bonding ring 208 for fusing with the first bonding ring 218 in order to jointly surround the accelerometer 202, the integrated circuit 102, the first electrical connection unit and the second electrical connection unit.

The integrated circuit 102 is formed on the second base 117 and is electrically connected to the second electrical connection unit. The second electrical connection unit includes a second bonding pad 105 and a pair of second additional bonding pads 116 formed on the second bonding pad 105. The second bonding pad 105 is made of metal material. The second bonding pad 105 and the pair of second additional bonding pads 116 are surrounded by the second bonding ring 108. Each second additional bonding pad 116 is formed by a second UBM layer 120 and a second solder layer 115 formed on the second UBM layer 120. The second UBM layer 120 is similar to the UBM layer and includes an adhesion layer 111, a diffusion barrier layer 112, a wetting layer 113 and an oxidation barrier layer 114. Each of the layers 111, 112, 113, 114 function the same as the corresponding layers 213, 212, 211, 210 described above.

The second bonding ring 108 can be an organic ring formed by spin process or spraying process, or can be composed of a second metal ring 103 formed on the second chip 106, a third UBM layer 119 formed on the second metal ring 103 and a second solder layer 118 formed on the third UBM layer 119. The second solder layer 118 can be formed of a first alloy of Sn, Ag, Cu, or a second alloy of Sn, Cu, Ni, or a third alloy of Sn, Au, or other alloys. In such arrangement, the first and the second bases 208, 117 together with the first and the second bonding rings 218, 108 jointly form a RF chamber for EMI protection.

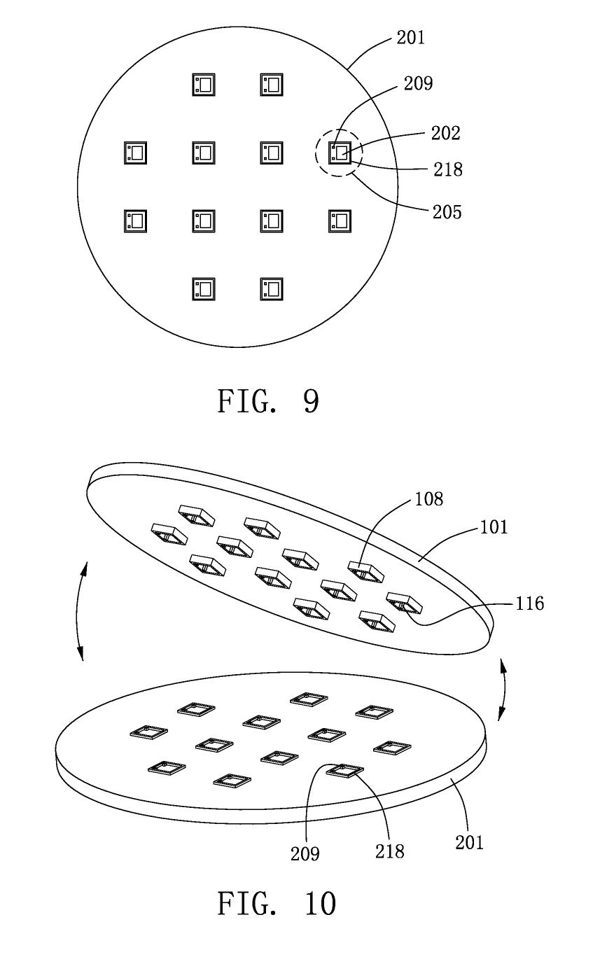

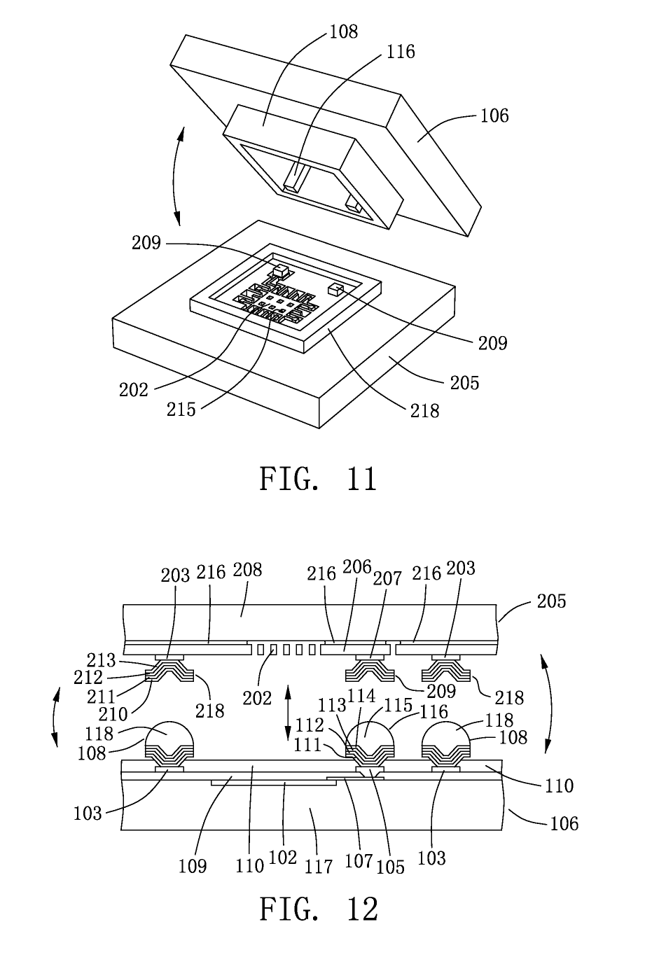

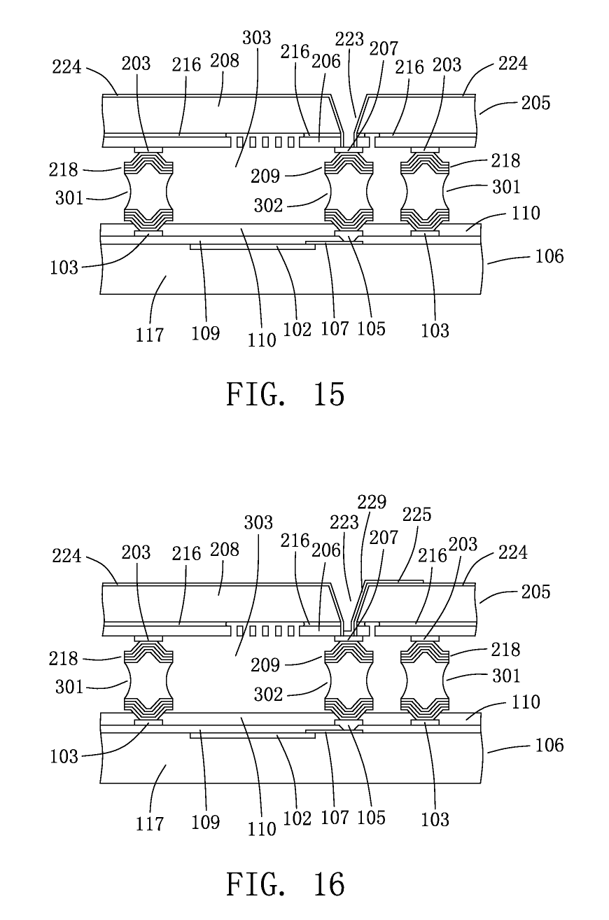

Please refer to the FIGS. 8 to 17, the processing steps for manufacturing the package are as follows: firstly, providing a first wafer 201 and a second wafer 101, respectively, as shown in FIGS. 8&9. The first wafer 201 is provided with the plurality of first chips 205 each comprising the accelerometer 202 and the first bonding pad 207 etc. The second wafer 101 is provided with the plurality of second chips 106 formed on the second base 117 by traditional integral circuit mounting process. Each second chip 106 includes the integrated circuit 102 corresponding to the accelerometer 202 and the second electrical connection unit corresponding to the first bonding pad 207.

Referring to FIG. 5, secondly, the first additional bonding pads 209 are formed on the first bonding pad 207, and the first bonding ring 218 is formed to surround the accelerometer 202 under a condition that the first additional bonding pads 209 and the first bonding pad 207 are disposed in the first bonding ring 218. Each first additional bonding pad 209 is formed by the UBM layer. The first bonding ring 218 is composed of the first metal ring 203 and the first UBM layer as shown in FIG. 3, wherein the first bonding ring 218 is formed by steps of: a) providing the first metal ring 203 surrounding the accelerometer 202; b) providing the first UBM layer formed on the first metal ring 203. The first UBM layer includes the adhesion layer 213, the diffusion layer 212, the wetting layer 211 and the oxidation barrier layer 210. The forming methods of the layers 213, 212, 211, 210 include evaporation, electroplate, chemical plating and printing etc. For example, depositing an adhesion layer on the accelerometer 202, then etching the adhesion layer to form the first bonding ring 218, and then depositing conductive-material layers required by the first UBM layer on the adhesion layer by sputtering, and finally etching undesired portions of the conductive-material layers to form the first UBM layer; The first UBM layer is then protected by an adhesive coating glue after the first UBM layer is finished. Then, the silica layer 216 is etched by flooding fluorhydric acid through slits 219 and the release holes 215, and the mass block is freely moveable because an air gap is formed under the mass block and the combs 221. Besides, the first bonding ring 218 can be of other structures such as an organic ring formed by spin process or spraying process.

Thirdly, the corresponding second additional bonding pads 116 are formed on the second bonding pad 105 and a second bonding ring 108 is formed on the second chip 106. Each second additional bonding pad 116 is formed by the second UBM layer 120 and the solder ball 116 is formed on the second solder layer 115. Each second UBM layer 120 is similar to the UBM layer and includes the adhesion layer 111, the diffusion barrier layer 112, the wetting layer 113 and the oxidation barrier layer 114. The forming methods of the layers 111, 112, 113, 114 include evaporation, electroplate, chemical plating and printing etc. Referring to FIG. 6, for example, depositing an adhesion layer on a dielectric layer 109 and a passivation layer 110 of the integrated circuit 102, then etching the adhesion layer to form the second metal ring 103 and the figure of the second additional bonding pads 116, then depositing conductive-material layers required by the second UBM layer 120 on the adhesion layer by sputtering and then etching undesired portions of the conductive-material layers to form the second UBM layer 120. The second bonding ring 108 is composed of the second metal ring 103, the third UBM layer 119 and the second solder layer 118. The forming steps of the second bonding ring 108 include: a) forming the second metal ring 103 and the second electrical connection unit on the second chip 106, simultaneously; b) forming the third UBM layer 119 on the second metal ring 103; c) forming the second solder layers 115, 118 on the corresponding additional UBM layer and the second UBM layer 120. The second solder layers 115, 118 are of the same material. Continue to use etching and plating methods to achieve the figure of the second solder layer 115, and then the final second bonding ring 108 and the second solder layer 115 can appear under reflow process of certain temperature. Besides, the second bring 108 can be of other structure such as an organic ring formed by spin process or spraying process as well.

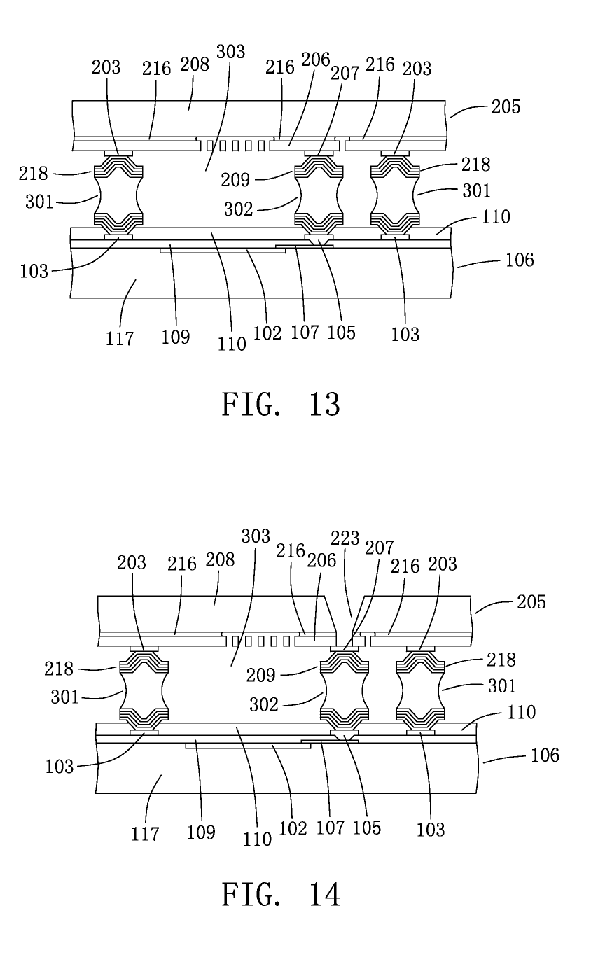

Fourthly, referring to FIGS. 10 & 11, the first wafer 201 and the second wafer 101 are coupled together with the first additional bonding pads 209 fusing with the second solder layers 115 of the second additional bonding pads 116 in order to establish electrical connection between the accelerometer 202 and the integrated circuit 102. Simultaneously, the first and the second bonding rings 218, 108 fuse with each other to form a hermetical cavity surrounding the accelerometer 202, the integrated circuit 102, the first bonding pad 207 and the second bonding pad 105. Referring to FIGS. 12 and 13, when the first the third UBM layers are selected for combining the first bonding ring 218 and the second bonding ring 108, in assembly, the first and the second bonding rings 218, 108, and the first and the second additional bonding pads 209, 116 are aligned with each other, respectively. Then, under certain pressure and temperature, the second solder layer 115 and the first additional bonding pads 209 fuse into a first adhesion unit 302. Simultaneously, the first solder layer 118 of the second bonding ring 108, and the first solder layer 118 of the second bonding ring 108, and the wetting layer 211 and the oxidation barrier layer 210 of the first bonding ring 218 fuses into a second adhesion unit 301. Under this condition, the accelerometer 202 is electrically connected to the integrated circuit 102 through the circuit lines 236, the first bonding pad 207, the first additional bonding pads 209, the first adhesion unit 302 and the second bonding pad 105. Besides, the second adhesion unit 301 forms a heretical cavity 303 with the accelerometer 202 disposed therein. The hermetical cavity 303 can be vacuum or be filled in some inert gas. The hermetical cavity 303 can be formed under certain pressure and temperature when the first and the second wafers 201, 101 are coupled with each other. Besides, the first and the second bonding rings 218, 108 can be organic rings, and under this circumstance, the fusion method of the first and the second bonding rings 218, 108 is similar to the above-described fusion method and is obvious to those of ordinary skill in the art. So, detailed description is omitted herein.

Fifthly, after the first and the second wafers 201, 101 are coupled with each other, a back wall of the first wafer 201 is selected to be reduced in height. The back wall is etched to get a perforation figure through the first base 208, the silica layer 216 and the MEMS layer 206. The figure is then etched in order to get a through hole 223 extending through the first wafer 201. The through hole 223 can be of column shape or conoid shape and is corresponding to the first bonding pad 207, as best shown in FIG. 3.

Sixthly, the first insulating layer 224 is deposited on the back wall of the first base 208 through low temperature deposition methods such as Plasma-Enhanced Chemical Vapor Deposition (PECVD). Then, the undesired parts of the first insulating layer 224 disposed in the through hole 223 is etched in order that the first bonding pad 207 can be exposed to the outside through the through hole 223.

Seventhly, the electrical connecting layer 225 is formed on the first insulating layer 224 through methods of evaporation, electroplate, chemical plating and printing etc. The electrical connecting layer 225 can be made of Al, Ti, Wu, Ni or other materials. Simultaneously, a circuit line 229 is provided for electrically connecting the first bonding pad 207 and the electrical connecting layer 225.

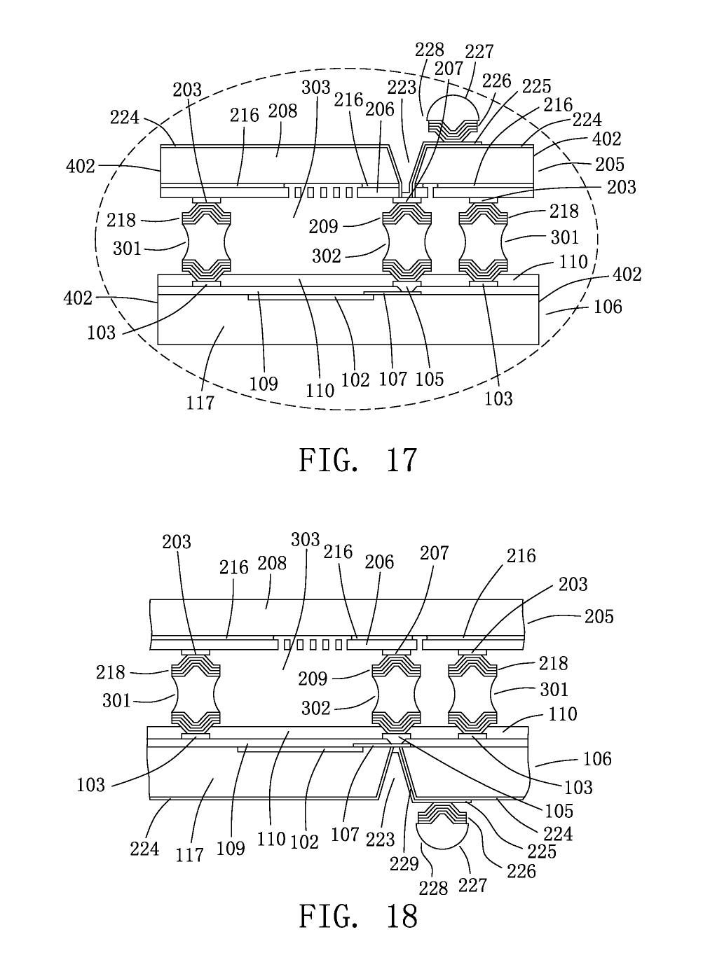

Eighthly, as shown in FIG. 17, the first external bonding portion 228 is formed on the electrical connecting layer 225 and comprises the additional UBM layer 226 formed on the electrical connecting layer 225, and the solder ball 227 formed on the additional UBM layer 226. The additional UBM layer 226 is the same as the UBM layer and includes an adhesion layer, a diffusion barrier layer, a wetting layer and an oxidation barrier layer. The forming materials and functions of the layers of the additional UBM layer 226 are the same as the corresponding layers of the UBM layer. So, detailed description is omitted herein.

Finally, the first and the second wafers 201, 101 are cut off simultaneously to get a plurality of independent packages. The easy damage movable parts of the MEMS device is protected since the cutting process is arranged following the packaging process of the MEMS device. Besides, expensive cutting methods such as laser cutting can be avoided for cost down. As shown in FIG. 17, since the division positions are adjacent to the first and the second adhesion units 302, 301, and lateral sides of the first chip 205 are aligned with the corresponding lateral sides of the second chip 106 as a result that the material of the first and the second wafers 201, 101 are great saved. The package comprises the first and the second chips 205, 106 so that each package can be plastically packed or can be directly adapted for SMT or Flip-Chip Solder process instead of expensive metal packaging or ceramic packaging for lower cost.

While a specific embodiment has been illustrated and described, numerous modifications come to mind without significantly departing from the spirit of the invention. However, in other embodiments, the manufacturing steps of the package needn't completely follow the steps describe above. For example, the first and the second metal rings 203, 103 can be formed simultaneously with the first and the second bonding pads 207, 105. Or, the through hole 223 and the first external bonding portion 228 can be formed after the first electrical connection unit appears, and then the first and the second wafers 201, 101 are coupled with each other.

Please refer to FIG. 18, a second embodiment of the present invention similar to the first embodiment is disclosed. The differences between them are that the through hole 223 is formed in the back wall of the second base 108 and the first external bonding portion 228 is formed on the second base 108. The first insulating layer 224 is deposited on the back wall of the second base 108. Then, the undesired parts of the first insulating layer 224 disposed in the through hole 223 is etched in order that the second bonding pad 105 can be exposed to the outside through the through hole 223. The electrical connecting layer 225 is formed the first insulating layer 224 through methods of evaporation, electroplate, chemical plating and printing etc. The electrical connecting layer 225 can be made of Al, Ti, Wu, Ni or other materials. Simultaneously, the circuit line 229 is provided to electrically connect the second bonding pad 105 and the electrical connecting layer 225.

While specific embodiments have been illustrated and described, numerous modifications come to mind without significantly departing from the spirit of the invention, and the scope of protection is only limited by the scope of the accompanying claims.

What is claimed is:

1. A package with a semiconductor device and an integrated circuit mounted therein comprising:
a first chip having a first base with the semiconductor device mounted on one side of the first base, a first electrical connection unit, a first bonding ring surrounding the semiconductor device, a first insulating layer formed on the other side of the first base and a first external bonding portion formed on the first insulating layer under a condition that the first external bonding portion is electrically connected to the first electrical connection unit; and
a second chip coupled to the first chip and comprising the integrated circuit corresponding to the semiconductor device, a second electrical connection unit fusing with the first electrical connection unit, and a second bonding ring fusing with the first bonding ring in order to form a hermetic cavity surrounding the semiconductor device, the integrated circuit, the first electrical connection unit and the second electrical connection unit.

2. The package as claimed in claim 1, wherein the first external bonding portion comprises a first electrical connecting layer disposed on the first insulating layer and a first additional electrical connecting layer connecting the first electrical connecting layer and the first electrical connection unit.

3. The package as claimed in claim 2, wherein the first external bonding portion comprises a first additional UBM layer formed on the first electrical connecting layer and a first solder layer formed on the first additional UBM layer, the first solder layer comprising a solder ball electrically connected to the first electrical connection unit under a condition that the solder ball is adapted for being soldered to an external board.

4. The package as claimed in claim 2, wherein the first electrical connection unit comprises a first bonding pad connecting the first external bonding portion, the package further defining a through hole extending through the first chip and corresponding to the first bonding pad, the first bonding pad being exposed to the outside through the through hole.

5. The package as claimed in claim 3, wherein the first additional UBM layer comprises an adhesion layer formed on the first electrical connecting layer, a diffusion barrier layer formed on the adhesion layer, a wetting layer formed on the diffusion barrier layer, and an oxidation barrier layer formed on the wetting layer.

6. The package as claimed in claim 1, wherein the first insulating layer is made of silica or silicon nitride.

7. The package as claimed in claim 1, wherein lateral sides of the first and the second chips are align with each other.

8. A package with a semiconductor device and an integrated circuit mounted therein comprising:
a first chip having the semiconductor device, a first electrical connection unit and a first bonding ring surrounding the semiconductor device; and
a second chip coupled to the first chip and comprising a second base with the integrated circuit mounted on one side of the second base, a second electrical connection unit and a second bonding ring, the integrated circuit being opposite to and corresponding to the semiconductor device, the first and the second electrical connection units being fused with each other, similarly, the second bonding ring fusing with the first bonding ring in order to form a hermetic cavity surrounding the semiconductor device, the integrated circuit, the first electrical connection unit and the second electrical connection unit; wherein the second chip further comprises a second insulating layer formed on the other side of the second base and a second external bonding portion disposed on the second insulating layer under a condition that the second external bonding portion is electrically connected to the second electrical connection unit.

9. The package as claimed in claim 8, wherein the second external bonding portion comprises a second electrical connecting layer disposed on the second insulating layer and a second additional electrical connecting layer connecting the second electrical connecting layer and the second electrical connection unit.

10. The package as claimed in claim 9, wherein the second external bonding portion comprises a second additional UBM layer formed on the second electrical connecting layer and a second solder layer formed on the second additional UBM layer, the second solder layer comprising a solder ball electrically connected to the second electrical connection unit under a condition that the solder ball is adapted for being soldered to an external board.

11. The package as claimed in claim 9, wherein the second electrical connection unit comprises a second bonding pad connecting the second external bonding portion, the package further defining a through hole extending through the second chip in order that the second bonding pad is exposed to the outside through the through hole.

12. The package as claimed in claim 10, wherein the second additional UBM layer comprises an adhesion layer disposed on the second electrical connecting layer, a diffusion barrier layer formed on the adhesion layer, a wetting layer formed on the diffusion barrier layer, and an oxidation barrier layer formed on the wetting layer.

13. The package as claimed in claim 8, wherein the second insulating layer is made of silica or silicon nitride.

14. A method for manufacturing a package comprising steps of:
a) providing a first wafer and a second wafer, the first wafer being provided with a first base, a semiconductor device mounted on one side of the first base, a first bonding pad and a first bonding ring enclosing the semiconductor device; the second wafer being provided with a second base, an integrated circuit mounted on one side of the second base, a second bonding pad and a second bonding ring enclosing the integrated circuit;
b) coupling the first and the second wafers with each other under a condition that the first and the second bonding pads are electrically connected with each other, and the first and the second bonding rings fuse with each other to jointly form a hermetic cavity which surrounds the semiconductor device, the integrated circuit, the first bonding pad and the second bonding pad;
c) defining a first through hole on the other side of the first base with the first through hole reaching the first bonding pad; or defining a second through hole on the other side of the second base with the second through hole reaching the second bonding pad;
d) depositing a first insulating layer on the other side of the first base and then etching undesired portions of the first insulating layer to expose the first bonding pad through the first through hole; or depositing a second insulating layer on the other side of the second base and then etching undesired portions of the second insulating layer to expose the second bonding pad through the second through hole;
e) forming a first external bonding portion on the first insulating layer under a condition that the first external bonding portion is electrically connected to the first bonding pad for electrically connecting to an external circuit; or forming a second external bonding portion on the second insulating layer under a condition that the second external bonding portion is electrically connected to the second bonding pad for electrically connecting to an external circuit; and
f) cutting out the first and the second wafers simultaneously to obtain each independent package.

15. The method for manufacturing a package as claimed in claim 14, wherein the first external bonding portion comprises a first electrical connecting layer formed on the first insulating layer and a first additional electrical connecting layer connecting the first electrical connecting layer and the first bonding pad; the second external bonding portion comprising a second electrical connecting layer formed on the second insulating layer and a second additional electrical connecting layer connecting the second electrical connecting layer and the second bonding pad.

16. The method for manufacturing a package as claimed in claim 15, wherein the first external bonding portion comprises a first additional UBM layer formed on first electrical connecting layer and a first solder layer formed on the first additional UBM layer, and wherein the first solder layer comprises a solder ball electrically connected to the first bonding pad under a condition that the solder ball is adapted for being soldered to the external circuit; the second bending portion comprising a second additional UBM layer formed on the second electrical connecting layer and a second solder layer formed on the second additional UBM layer, and wherein the second solder layer comprises a solder ball electrically connected to the second bonding pad under a condition that the solder ball is adapted for being soldered to the external circuit.

17. The method for manufacturing a package as claimed in claim 16, wherein the first additional UBM layer comprises a first adhesion layer disposed on the first electrical connecting layer, a first diffusion barrier layer formed on the first adhesion layer, a first wetting layer formed on the first diffusion barrier layer, and a first oxidation barrier layer formed on the first wetting layer; similarly, the second additional UBM layer comprising a second adhesion layer disposed on the second electrical connecting layer, a second diffusion barrier layer formed on the second adhesion layer, a second wetting layer formed on the second diffusion barrier layer, and a second oxidation barrier layer formed on the second wetting layer.

18. The method for manufacturing a package as claimed in claim 14, wherein neither the first nor the second insulating layer is made of silica or nitride.

19. The method for manufacturing a package as claimed in claim 14, wherein corresponding lateral sides of the first and the second chips are aligned with each other.

20. The method for manufacturing a package as claimed in claim 14, wherein the first and the second through holes are of column shape or conoid shape.
